(19) United States
(12) Patent Application Publication
(10) Pub. No.: US 2024/0162901 A1
(43) Pub. Date: May 16, 2024

(54) QUBIT PROCESSING METHOD AND QUANTUM CIRCUIT

(71) Applicant: Alibaba Damo (Hangzhou) Technology Co., Ltd., Hangzhou (CN)

(72) Inventor: Tenghui WANG, Hangzhou (CN)

(21) Appl. No.: 18/508,799

(22) Filed: Nov. 14, 2023

(30) Foreign Application Priority Data
Nov. 16, 2022 (CN) 202211457950.8

(51) Int. Cl. H03K 17/92; G06N 10/40

(52) U.S. Cl. CPC H03K 17/92; G06N 10/40

(57) ABSTRACT

A qubit processing method, includes: controlling a qubit to be biased at a preset frequency; acquiring a relationship between a frequency of a tunable resonator and a flux bias applied to the tunable resonator, the tunable resonator being a resonator coupled with the qubit; determining a target flux bias corresponding to energy level splitting of the tunable resonator based on the relationship, the energy level splitting representing that the tunable resonator resonates with the qubit; and applying the target flux bias to the tunable resonator for a preset time period to initialize the qubit.

### CROSS-REFERENCE TO RELATED APPLICATIONS

The disclosure claims the benefits of priority to Chinese Application No. 202211457950.8, filed on Nov. 16, 2022, which is incorporated herein by reference in its entirety.

### TECHNICAL FIELD

The present disclosure relates to the field of quantum technology, and specifically relates to a qubit processing method, and a quantum circuit.

### BACKGROUND

Different from the traditional classical physical quantity that low level and high level represent 0 and 1 respectively, the physical quantities such as spin of electrons and polarization of light are used as a 0 state and a 1 state respectively of a qubit in the field of quantum calculation. Without any operation, an ideal qubit is to be 100% in the 0 state. However, because the temperature is still on an order of tens of mK, it will cause a small amount of thermal excitation and there will still be some residual 1 state. This partial residue will bring an error in the initial state, leading to greater inaccuracy in subsequent calculations.

When initializing the qubit, a direct microwave driving mode is generally adopted to excite the quantum state in the bit into a coupled readout resonator. However, the initialization required by the above method is too long, and the required microwave power is also large. At the same time, large-scale multi-bit initialization has the problem of low efficiency.

### SUMMARY OF THE DISCLOSURE

Embodiments of the present disclosure provide a qubit processing method. The method includes: controlling a qubit to be biased at a preset frequency; acquiring a relationship between a frequency of a tunable resonator and a flux bias applied to the tunable resonator, the tunable resonator being a resonator coupled with the qubit; determining a target flux bias corresponding to energy level splitting of the tunable resonator based on the relationship, the energy level splitting representing that the tunable resonator resonates with the qubit; and applying the target flux bias to the tunable resonator for a preset time period to initialize the qubit.

Embodiments of the present disclosure provide another qubit processing method. The method includes: acquiring flux bias applied to a tunable resonator through multiple adjustments and measured frequencies corresponding to the flux bias subjected to the multiple adjustments, the tunable resonator being a resonator coupled with a qubit; based on the flux bias through the multiple adjustments and the measured frequencies corresponding to the flux bias through the multiple adjustments, determining a relationship between the frequency of the tunable resonator and the flux bias applied to the tunable resonator; and determining a target flux bias corresponding to energy level splitting of the tunable resonator based on the relationship, the energy level splitting representing that the tunable resonator resonates with the qubit, and initialization of the qubit being realized after the target flux bias is applied to the tunable resonator for a preset time period.

Embodiments of the present disclosure provide a quantum circuit. The quantum circuit includes: a qubit readout resonator; a qubit coupled with a readout line through the qubit readout resonator, and used for being biased at a preset frequency; and a tunable resonator coupled with the readout line and coupled with the qubit, wherein the tunable resonator is configured to initialize the qubit by applying a target flux bias enabling energy level splitting of the tunable resonator for a preset time period, the energy level splitting representing that the tunable resonator resonates with the qubit.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1 shows a hardware structure block diagram of an exemplary computer terminal for implementing a qubit processing method, according to some embodiments of the present disclosure.

FIG. 2 is a flowchart of an exemplary qubit processing method, according to some embodiments of the present disclosure.

FIG. 3 is a flowchart of another exemplary qubit processing method, according to some embodiments of the present disclosure.

FIG. 4 is a schematic diagram of an exemplary quantum circuit, according to some embodiments of the present disclosure.

FIG. 5 is a schematic diagram of an exemplary circuit in qubit initializing, according to some embodiments of the present disclosure.

FIG. 6 illustrates a flowchart of an exemplary qubit initialization, according to some embodiments of the present disclosure.

FIG. 7 is a schematic structural diagram of an exemplary qubit processing apparatus, according to some embodiments of the present disclosure.

FIG. 8 is a schematic structural diagram of another exemplary qubit processing apparatus, according to some embodiments of the present disclosure.

FIG. 9 is a schematic structural diagram of a computer terminal, according to some embodiments of the present disclosure.

### DETAILED DESCRIPTION

Reference can now be made in detail to example embodiments, examples of which are illustrated in the accompanying drawings. The following description refers to the accompanying drawings in which the same numbers in different drawings represent the same or similar elements unless otherwise represented. The implementations set forth in the following description of example embodiments do not represent all implementations consistent with the disclosure. Instead, they are merely examples of apparatuses and methods consistent with aspects related to the disclosure as recited in the appended claims. Particular aspects of present disclosure are described in greater detail below. The terms and definitions provided herein control, if in conflict with terms and/or definitions incorporated by reference.

According to some embodiments of the present disclosure, a qubit processing method is provided. It is be noted that the steps shown in the flowchart of the accompanying drawings may be executed in a computer system such as a set of computer-executable instructions, and moreover, although a logical order is shown in the flowchart, in some cases, the steps shown or described may be performed in an order different from that shown or described herein.

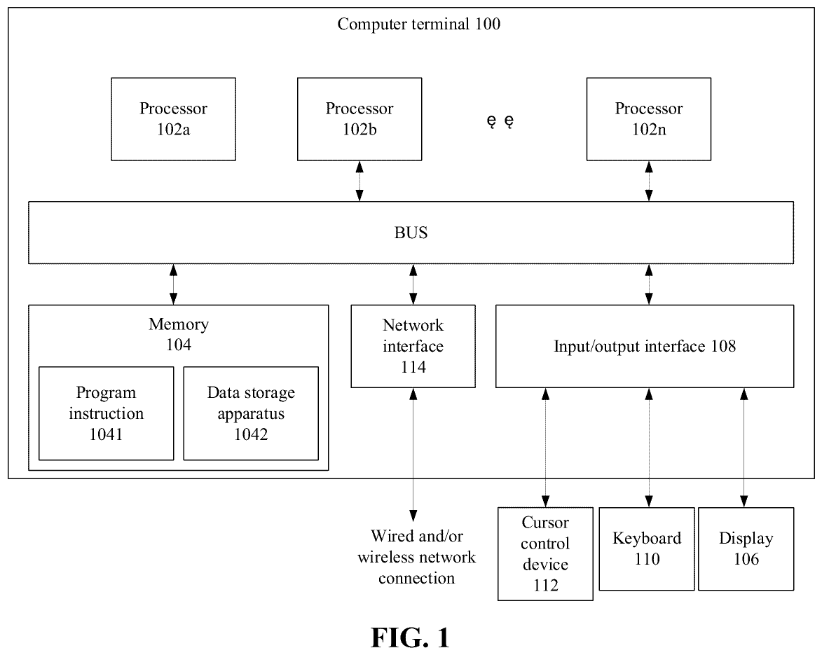

The methods provided according to the embodiments of the present disclosure may be executed in a mobile terminal, a computer terminal, or a similar arithmetic apparatus. FIG. 1 shows a hardware structure block diagram of a computer terminal 100 (or mobile device) for implementing a qubit processing method, according to some embodiments of the present disclosure. As shown in FIG. 1, computer terminal 100 (or mobile device) may include one or more processors (shown in the figure as 102a, 102b . . . 102n, and the processors may include but be not limited to processing apparatuses such as a microprocessor MCU or a programmable logic device FPGA), a memory 104 configured to store data, and a transmission apparatus configured to perform a communication function. In addition, computer terminal 100 may further include a display 106, an input/output interface (I/O interface) 108, a keyboard 110, a cursor control device 112, a universal serial bus (USB) port (which may be included as one of the ports of a BUS), a network interface 114, a power supply and/or a camera. It is appreciated that the structure shown in FIG. 1 is only a schematic diagram and does not cause limitation to the structure of the electronic apparatus. For example, the computer terminal 100 may further include more or less components than those shown in FIG. 1, or has different configurations from those shown in FIG. 1.

It is be noted that the one or more processors and/or other data processing circuits may be generally called as a “data processing circuit” in this text. The data processing circuit may be completely or partially embodied as software, hardware, firmware or any other combination. In addition, the data processing circuit may be a single independent processing module or be completely or partially combined into any one of other elements in the computer terminal 100 (or mobile device). As involved in the embodiments of the present disclosure, the data processing circuit serves as a processor control (such as selection of a variable resistance terminal path connected with the interface).

Memory 104 can be configured to store software programs of application software and modules, such as a program instruction/data storage apparatus corresponding to the qubit processing method according to the embodiments of the present disclosure; and the processor executes various function applications and data processing by running the software programs and the modules stored in memory 104, namely, a qubit processing method for the application programs is realized. Memory 104 can include a high-speed random access memory and can also include a nonvolatile memory, such as one or more magnetic storage apparatuses, flash memories or other nonvolatile solid-state memories. In some examples, memory 104 can further include memories remotely arranged relative to the processor, and the remote memories may be connected to computer terminal 100 through a network. The examples of the network include but are not limited to the Internet, an intranet, a local area network, a mobile communication network and a combination thereof.

The transmission apparatus is configured to receive or transmit data through a network. The specific examples of the network can include a wireless network provided by a communication provider of computer terminal 100. In one example, the transmission apparatus includes a network interface controller (NIC), and the network interface controller can be connected with other network devices through a base station so as to communicate with the internet. In one example, the transmission apparatus may be a radio frequency (RF) module and is configured to communicate with the internet in a wireless mode.

Display 106 may be a touch screen type liquid crystal display (LCD) for example, and the liquid crystal display enables a user to interact with a user interface of computer terminal 100 (or mobile device).

It is to be noted that in some alternative embodiments, the computer device (or mobile device) shown in FIG. 1 may include a hardware element (including a circuit), a software element (including computer codes stored on the computer readable medium) or a combination of the hardware element and the software element. It is to be pointed out that FIG. 1 is only one example of a specific example and aims at showing the type of components which can be in the computer device (or mobile device).

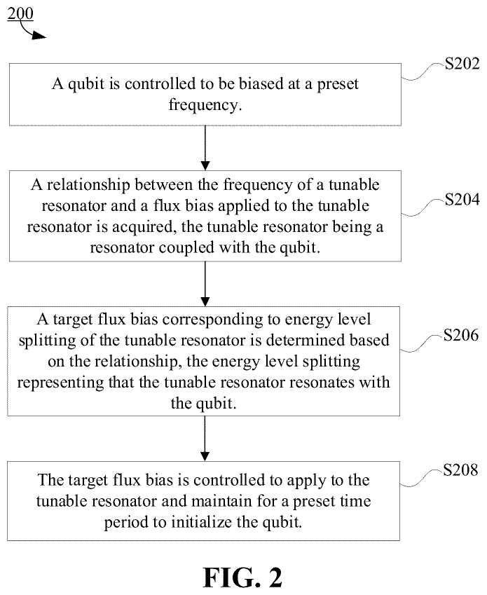

Under the above operating environment, the present disclosure provides a qubit processing method as shown in FIG. 2. FIG. 2 is a flowchart of an exemplary qubit processing method 200, according to some embodiments of the present disclosure. As shown in FIG. 2, method 200 includes steps S202 to S208.

At step S202, a qubit is controlled to be biased at a preset frequency.

In some embodiments, qubit processing method 200 may be performed by a terminal or a server. The terminal may be various types of terminals, such as a computer terminal, a mobile terminal, and a virtual terminal, but no matter which type of terminal, a certain computing capability meeting computing requirements needs to be achieved. The server may be in various forms, such as a single computer device, a computer cluster including a plurality of computers, a local computing unit, and a remote cloud server.

In some embodiments, the preset frequency may be any frequency to which the qubit may be adjusted, that is, the qubit may be a frequency-adjustable qubit. When the qubit is controlled to be biased at the preset frequency, the frequency of the qubit is related to the environment where the qubit is located, for example, the frequency of the qubit is related to the flux bias applied to the qubit. There is a certain relationship between the frequency of the qubit and the flux bias applied to the qubit. When the frequency of the qubit is controlled, the frequency of the qubit may be controlled by controlling the flux bias applied to the qubit based on the relationship. For example, when a relationship curve between the frequency of the qubit and the flux bias applied to the qubit is known, the flux bias corresponding to the target frequency is determined based on the target frequency to which the qubit is to be modulated, and then the determined flux bias is applied to the qubit, that is, the frequency of the qubit is the target frequency to which the qubit is to be modulated.

In some embodiments, the control mode for controlling the qubit to be biased at the preset frequency includes the mode of controlling the frequency by accurately controlling the flux bias applied to the qubit, and also includes other control modes, for example, under a condition that the external environment of the qubit is continuously changed, a mode of directly measuring the qubit is adopted, and the frequency of the qubit obtained through measurement is determined when the frequency is a target frequency.

In some embodiments, the qubits may be of multiple types, for example, Fluxonium qubits, Transmon qubits, charge qubits, phase qubits and other types of frequency-adjustable qubits, which are not limited in the present disclosure. Fluxonium is a type of superconducting qubit, which is composed of a Josephson junction in parallel with an inductor and capacitor. In this composition, there is a large inductance (usually made of a large number of Josephson junction (e.g., 100) arrays or high dynamic inductance materials). The electric energy EC corresponding to the capacitance, the magnetic energy EL corresponding to the inductor, and the Josephson energy EJ are close to each other (about an order of magnitude).

At step S204, a relationship between the frequency of a tunable resonator and a flux bias applied to the tunable resonator is acquired, the tunable resonator being a resonator coupled with the qubit. A tunable resonator is a resonator having a frequency that is tunable, for example, a resonator based on a coplanar waveguide.

In some embodiments, a tunable resonator is a resonator coupled with the qubit. The tunable resonator can be realized in multiple modes, for example, in a superconducting quantum interference device (SQUID) mode, or a unijunction direct-current bias realization mode. Superconducting quantum interference device (SQUID) is an instrument developed based on the Josephson effect and the principle of magnetic flux quantization. In the present disclosure, it refers to a loop structure formed by two Josephson junctions, which is embedded in a coplanar waveguide and serves as a magnetic flux modulated adjustable inductor. The coupling between the tunable resonator and the qubit may be considered as strong coupling, that is, the energy level of the qubit may be adjusted through adjustment of the tunable resonator, which is a strong correlation, thereby realizing the initialization of the qubit. In other words, when the tunable resonator is coupled with the qubit, the influence of the tunable resonator on the qubit is relatively large, and the qubit can be initialized quickly and efficiently. Qubit initialization means initializing qubits to a ground or excited state.

In some embodiments, when acquiring the relationship between the frequency of the tunable resonator and the flux bias applied to the tunable resonator, generally, a plurality of flux bias may be applied to the tunable resonator, and for each of the plurality of flux bias, a frequency of the tunable resonator is read by adopting a readout line coupled with the flux bias. The relationship between the frequency of the tunable resonator and the flux bias applied to the tunable resonator is simulated based on the plurality of flux bias and the frequencies corresponding to the plurality of flux bias. The specific simulation mode may be realized by establishing a related mathematical model, i.e., the relationship between the frequency of the tunable resonator and the flux bias applied to the tunable resonator is simulated through an established mathematical model.

In some embodiments, when acquiring the relationship between the frequency of the tunable resonator and the flux bias applied to the tunable resonator, for example, the following mode may be adopted: measuring frequency of the tunable resonator after applying an initial flux bias to the tunable resonator, to obtain a measured frequency corresponding to the initial flux bias; changing the flux bias applied to the tunable resonator for multiple times based on the initial flux bias, to obtain measured frequencies corresponding to the flux bias through the multiple changes; and based on the measured frequency corresponding to the initial flux bias and the measured frequencies corresponding to the flux bias through the multiple changes, simulating the relationship between the frequency of the tunable resonator and the flux bias applied to the tunable resonator. When the plurality of flux bias and the relationship between the plurality of flux bias are acquired, in addition to the mode of establishing a mathematical model, simulation may also be carried out based on certain experience in order to improve the simulation speed. For example, when a preliminary relationship between the frequency of the tunable resonator and the flux bias applied to the tunable resonator may be known in advance, the preliminary relationship is properly adjusted based on the measured data, that is, the preliminary relationship is corrected by adopting the measured data, and thus the relationship between the frequency of the tunable resonator and the flux bias applied to the tunable resonator may be quickly acquired.

At step S206, a target flux bias corresponding to energy level splitting of the tunable resonator is determined based on the relationship, the energy level splitting representing that the tunable resonator resonates with the qubit. Energy level splitting is a physical phenomenon in which two energy levels with the same energy level experience energy level repulsion during resonance due to coupling.

In some embodiments, the tunable resonator resonates with the qubit, that is, a coupling system formed by the tunable resonator and the qubit generates resonance, and at the moment, the qubit exchanges energy with the tunable resonator. The above relationship represents the relationship between the frequency of the tunable resonator and the flux bias applied to the tunable resonator, and the relationship may also be called as a frequency spectrum of the tunable resonator. A position point where the tunable resonator generates energy level splitting may be clearly obtained from the frequency spectrum, and then the flux bias corresponding to the position point may be accurately determined in a manual or program mode, that is, the target flux bias.

In some embodiments, determining a target flux bias corresponding to energy level splitting of the tunable resonator based on the relationship includes: when a change curve showing the frequency changing along with the flux bias is adopted to represent the relationship, determining a position point where the change curve changes from one to two; and determining the flux bias corresponding to the position point as the target flux bias. When the relationship is represented based on the change curve, the position point corresponding to the target flux bias is determined based on the change curve, and thus the needed target flux bias may be determined easily and efficiently.

At step S208, the target flux bias is controlled to apply to the tunable resonator and maintain for a preset time period to initialize the qubit.

In some embodiments, the preset time period refers to a time period in which the qubit and the tunable resonator are subjected to energy exchange when the qubit resonates with the tunable resonator, so that energy of the qubits is completely transferred to the tunable resonator. The preset time period may be tens to hundreds of nanoseconds, for example, 20 ns, 30 ns, 40 ns, 50 ns, 100 ns, and 200 ns, etc.

In some embodiments, step S208 of controlling to apply the target flux bias to the tunable resonator and maintaining for a preset time period, to initialize the qubit includes: under a condition that a plurality of qubits are coupled to the tunable resonator, controlling to apply the target flux bias to the tunable resonator and maintaining for a preset time period, and performing batch initialization on the plurality of qubits.

According to the abovementioned embodiments, after the qubit is coupled with the tunable resonator, a resonance point which resonates with the qubit is determined by adjusting the frequency of the tunable resonator, that is, the target flux bias corresponding to the energy level splitting of the tunable resonator is determined; and then the target flux bias is applied to the tunable resonator, so that the tunable resonator resonates with the qubit, and the resonance maintains for a period of time to realize the initialization of the qubit. With this mode, the initialization of the qubit can be realized by simply modulating the flux bias of the tunable resonator, the method is simple and efficient, and the initialization efficiency of the qubit is effectively improved.

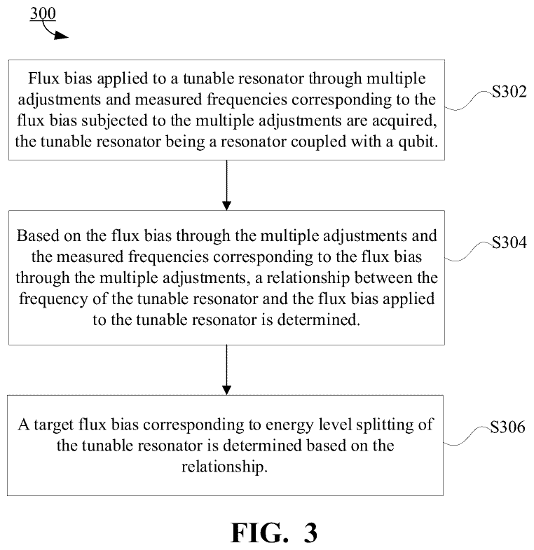

FIG. 3 is a flowchart of another exemplary qubit processing method according to some embodiments of the present disclosure. As shown in FIG. 3, the flow includes steps S302 to S306.

At step S302, flux bias applied to a tunable resonator through multiple adjustments and measured frequencies corresponding to the flux bias subjected to the multiple adjustments are acquired, the tunable resonator being a resonator coupled with a qubit.

At step S304, based on the flux bias through the multiple adjustments and the measured frequencies corresponding to the flux bias through the multiple adjustments, a relationship between the frequency of the tunable resonator and the flux bias applied to the tunable resonator is determined.

At step S306, a target flux bias corresponding to energy level splitting of the tunable resonator is determined based on the relationship. The energy level splitting represents that resonance occurs between the tunable resonator and the qubit. Initialization of the qubit is realized after the target flux bias is applied to the tunable resonator and maintained for a preset time period.

According to the abovementioned embodiments, the method includes the following steps: acquiring flux bias applied to a tunable resonator through multiple adjustments and measured frequencies corresponding to the flux bias subjected to the multiple adjustments; based on the flux bias through the multiple adjustments and the measured frequencies corresponding to the flux bias through the multiple adjustments, determining a relationship between the frequency of the tunable resonator and the flux bias applied to the tunable resonator; and determining a target flux bias corresponding to energy level splitting of the tunable resonator based on the relationship. According to this method, the target flux bias for initializing the qubit may be obtained based on simple adjustment and measurement. According to this method, the target flux bias for initialization is obtained through simple measurement and simulation of the measurement result; and the method for obtaining the target flux bias is simple and efficient, and then the qubit initialization efficiency is indirectly improved.

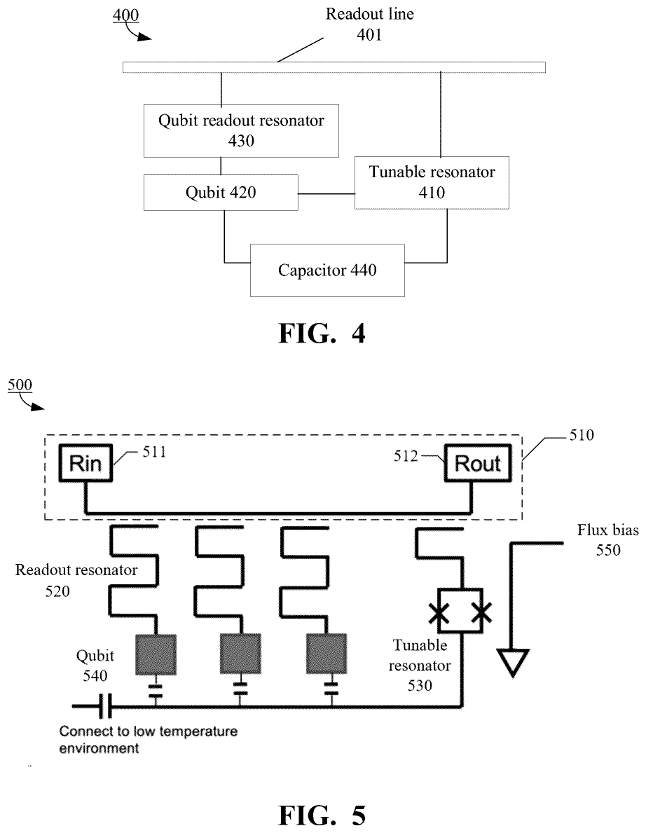

FIG. 4 is a schematic diagram of an exemplary quantum circuit 400, according to some embodiments of the present disclosure. As shown in FIG. 4, quantum circuit 400 includes: a tunable resonator 410, a qubit 420, and a qubit readout resonator 430. Qubits 420 are coupled with a readout line through qubit readout resonator 430. Tunable resonator 410 is coupled with the readout line. Tunable resonator 410 is coupled with qubit 420. Qubit 420 is used for being biased at a preset frequency. Tunable resonator 410 is configured to initialize qubit 420 by applying a target flux bias enabling energy level splitting of tunable resonator 410 and maintaining for a preset time period, and the energy level splitting represents that resonance occurs between tunable resonator 410 and qubit 420.

Through quantum circuit 400, the frequency of tunable resonator 410 may be measured for multiple times to obtain a target flux bias of tunable resonator 410 capable of resonating with qubit 420; and the target flux bias is applied to tunable resonator 410 and maintained for a certain time, so as to realize initialization of qubit 420. By adopting the quantum circuit, when the qubit is initialized, it is only needed to simply modulate the frequency of the tunable resonator to efficiently realize initialization of the qubit.

In some embodiments, quantum circuit 400 may further include a capacitor 440. Capacitor 440 is coupled with the qubit 420 and tunable resonator 410 respectively, and is configured to assist in initializing qubit 420. It is to be noted that the capacitor may be represented in a lower-temperature environment, the specific structure may be flexibly changed, and initialization of the qubit is assisted in being realized.

In some embodiments, tunable resonator 410 may be a superconducting quantum interference device. The preset time period may be tens to hundreds of nanoseconds.

Based on the foregoing embodiments, an optional implementation manner is provided.

The working frequency of qubit is usually very low, and it may be maintained in a thermal steady state with a large population in a 1 state. It is needed to initialize the qubit before working, and cool the system to reach a 0 state as much as possible. For example, Fluxonium, a newly discovered qubit, possesses several advantageous traits such as extended decoherence time and high nonlinearity, making it a viable contender in the race to achieve large-scale quantum computing in the future. Although its working frequency is usually very low, it tends to remain in a thermal steady state with a large population in a 1 state. For a large-scale Fluxonium chip, a subsequent parameter calibration process may be conveniently carried out only after the Fluxonium chip is initialized.

Based on the problems above, some modes of performing resonance between the qubit and the resonator are also proposed in related technologies to realize adjustment of the qubit, for example, the resonator is fixed in frequency, and resonance between the bit and the resonator is realized through bit frequency adjustment. However, this solution has high requirements for parameter setting of the resonator, and the resonator also has additional influences on the bits.

To avoid the problems, in some embodiments, a resonator with tunable frequency is utilized, and the frequency of the resonator is continuously changed, so that the resonator sequentially resonates with Fluxonium to exchange energy, and as a result, rapid initialization of a large number of chips is realized. The whole initialization process only involves magnetic flux square wave modulation, is simple and easy to implement, and effectively improves the qubit initialization efficiency.

FIG. 5 is a schematic diagram of an exemplary circuit 500 for qubit initialization, according to some embodiments of the present disclosure. As shown in FIG. 5, a readout line 510 (including a Rin 511 and a Rout 521) is coupled with a readout resonator 520 and a tunable resonator 530 of a qubit 540 respectively. Tunable resonator 530 is configured to adjust the frequency by changing the flux bias (amount) 550 of a superconducting quantum interference device (SQUID) on readout line 510.

Based on this schematic diagram of circuit 500, FIG. 6 illustrates a flowchart of an exemplary qubit initialization 600, according to some embodiments of the present disclosure. As shown in FIG. 6, qubit initialization 600 includes steps S602 to S606.

At step S602, the qubit is biased at a certain resonant frequency, the biased resonant frequency being not specifically limited. The qubit may be a frequency-adjustable qubit, that is, the resonant frequency may be any frequency to which the adjustable qubit may be adjusted. The adjustment of the frequency of the qubit may be determined based on the relationship between the frequency of the qubit and the magnetic flux applied to the qubit, and the corresponding frequency is obtained by adjusting the magnetic flux applied to the qubit based on the relationship, details of which will not be described herein.

At step S604, through continuous measurements, the relationship between the frequency and the magnetic flux (i.e., flux bias) of the tunable resonator can be obtained. Moreover, signals of energy level splitting of the tunable resonator may be shown on a spectrogram, and the position point of each signal corresponds to resonance of the tunable resonator and the qubit. The flux bias applied to the tunable resonator is adjusted, and the frequencies corresponding to the different flux bias are obtained through measurements by adjusting the different flux bias multiple times. The relationship between the frequencies of the tunable resonator and the flux bias is determined based on the flux bias adjusted multiple times and the frequencies corresponding to the flux bias adjusted multiple times. The position point corresponding to energy level splitting of the tunable resonator is determined based on the relationship. Then, the position point is determined to be the position point of resonance of the tunable resonator and the qubit, and the flux bias corresponding to the position point is obtained. The frequency of the qubit changes accordingly because the qubit is in a certain environment and may also be affected by the environment. Therefore, there might be a plurality of resonance points between the qubit and the tunable resonator. Through the processing above, the flux bias corresponding to each resonance point can be determined and recorded.

At step S606, a flux bias corresponding to each resonance point is recorded, and the tunable resonator is sequentially adjusted to corresponding position and maintained for tens to hundreds of nanoseconds to complete bit initialization. According to the method, the tunable resonators are sequentially adjusted to the flux bias corresponding to the resonance points, and tens to hundreds of nanoseconds are maintained after the adjustment, so that the energy of the qubit is completely released into the tunable resonator in a resonance mode, and the energy is further released to the external environment through the tunable resonator. As a result, the initialization of the qubit is realized.

In the exemplary implementation example described above, initialization is realized by coupling the resonator with variable frequency and the qubit. Since the frequency of the tunable resonator may be adjusted and the frequency of the tunable resonator is relatively high when the tunable resonator does not work, a high frequency may be kept without influencing normal work of the qubit under the condition of strong coupling with the qubit. According to the solution, the system may be globally initialized in a multi-bit system very easily, the operation and control are simple and easy to realize, and a large number of Fluxonium bits may be quickly initialized. According to some embodiments, large-scale initialization in the early stage may be completed before basic understanding of parameter determination of the qubit, so that subsequent accurate calibration of parameters of the qubit chip is facilitated.

It is to be noted that there might be various implementation modes of the tunable resonator, for example, a superconducting quantum interference device (SQUID) mode, and a unijunction direct-current bias mode.

It is to be noted that for the foregoing method embodiments, for the sake of simple description, they are expressed as a series of action combinations, but those skilled in the art should know that the present disclosure is not limited by the described action sequence. According to the present disclosure, certain steps may be performed in other orders or simultaneously. According to the present disclosure, certain steps may be performed in other orders or simultaneously. Secondly, those skilled in the art should also know that the embodiments described in the specification belong to preferred embodiments, and the actions and modules involved are not necessarily required by the present disclosure.

Through the description of the above embodiments, those skilled in the art can clearly know that the method according to the above embodiments can be realized by means of software and a necessary universal hardware platform, and the method can also be realized through hardware, but the former is a preferred embodiment in many cases. Based on this understanding, the technical solution of the prevent disclosure can be embodied in the form of a software product in essence or a part contributing to the prior art. The computer software product is stored in a computer readable storage medium (such as an ROM/RAM, a magnetic disk and an optical disk), and includes a plurality of instructions for enabling a terminal device (which can be a mobile phone, a computer, a server or network equipment and the like) to execute the methods of the embodiments of the present disclosure.

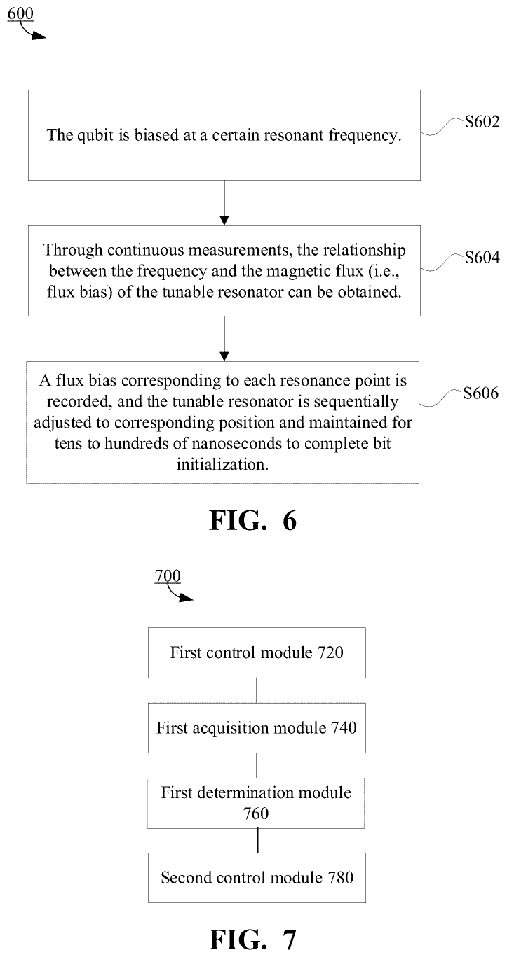

According to some embodiments of the present disclosure, an apparatus for implementing a qubit processing method 200 is further provided. FIG. 7 is a schematic structural diagram of an exemplary qubit processing apparatus 700, according to some embodiments of the present disclosure. As shown in FIG. 7, apparatus 700 includes: a first control module 720, a first acquisition module 740, a first determination module 760, and a second control module 780, and apparatus 700 will be described below.

First control module 720 is configured to control a qubit to be biased at a preset frequency. First acquisition module 740 is connected to first control module 720 and is configured to acquire a relationship between the frequency of a tunable resonator and a flux bias applied to the tunable resonator, the tunable resonator being a resonator coupled with the qubit. First determination module 760 is connected to first acquisition module 740 and configured to determine a target flux bias corresponding to energy level splitting of the tunable resonator based on the relationship, the energy level splitting representing that the tunable resonator resonates with the qubit Second control module 780 is connected to first determination module 760 and configured to control to apply the target flux bias to the tunable resonator and maintaining for a preset time period, so as to initialize the qubit.

It is to be noted that first control module 720, first acquisition module 740, first determination module 760, and second control module 780 correspond to steps S202 to S206 in method 200 respectively. The modules and the corresponding steps have the same examples and application scenarios, which are not limited to those disclosed in method 200. It is to be noted that the modules as part of the apparatus may run in computer terminal 100 provided according to the embodiments of the present disclosure.

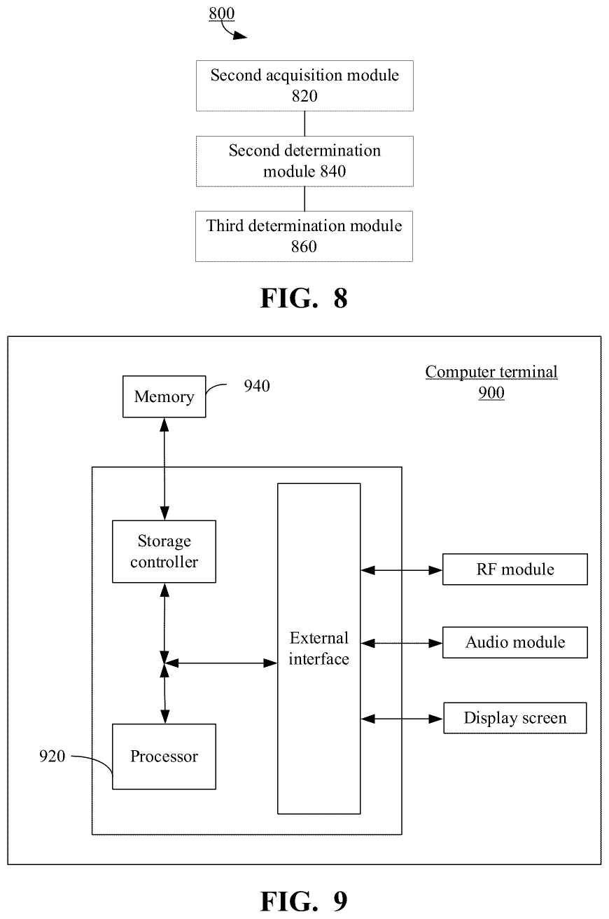

According to some embodiments of the present disclosure, an apparatus for implementing a qubit processing method 300 is further provided. FIG. 8 is a structure diagram of another exemplary qubit processing apparatus 800, according to some embodiments of the present disclosure. As shown in FIG. 8, apparatus 800 includes: a second acquisition module 820, a second determination module 840, and a third determination module 860. Apparatus 800 will be described below.

Second acquisition module 820 is configured to acquire flux bias applied to a tunable resonator through multiple adjustments and measured frequencies corresponding to the flux bias subjected to the multiple adjustments, the tunable resonator being a resonator coupled with a qubit. Second determination module 840 is connected to second acquisition module 820 and is configured to, based on the flux bias through the multiple adjustments and the measured frequencies corresponding to the flux bias through the multiple adjustments, determine a relationship between the frequency of the tunable resonator and the flux bias applied to the tunable resonator. Third determination module 860 is connected to second determination module 840 and is configured to determine a target flux bias corresponding to energy level splitting of the tunable resonator based on the relationship, the energy level splitting representing that the tunable resonator resonates with the qubit, and initialization of the qubit being realized after the target flux bias is applied to the tunable resonator and maintained for a preset time period.

It is to be noted that second acquisition module 820, second determination module 840, and third determination module 860 correspond to steps S302 to S310 in method 300 respectively. The modules and the corresponding steps have the same examples and application scenarios, which are not limited to those disclosed in method 300. It is to be noted that the modules as part of the apparatus may run in computer terminal 100 provided according to some embodiments of the present disclosure.

Some embodiments of the present disclosure may provide a computer terminal which may be any computer terminal device in a computer terminal group. In some embodiments, the foregoing computer terminal may also be replaced with a terminal apparatus such as a mobile terminal.

In some embodiments, the foregoing computer terminal may be located in at least one of a plurality of network devices of the computer network.

In this example, a computer terminal may execute program codes of the following steps in the qubit processing method of an application program: controlling a qubit to be biased at a preset frequency; acquiring a relationship between the frequency of a tunable resonator and a flux bias applied to the tunable resonator, the tunable resonator being a resonator coupled with the qubit; determining a target flux bias corresponding to energy level splitting of the tunable resonator based on the relationship, the energy level splitting representing that the tunable resonator resonates with the qubit; and controlling to apply the target flux bias to the tunable resonator and maintaining for a preset time period, and so as to initialize the qubit.

FIG. 9 is a structural diagram of an exemplary computer terminal 900, according to some embodiments of the present disclosure. As shown in FIG. 9, computer terminal 900 may include: one or more (only one shown in the figure) processors 920, a memory 940, etc.

Memory 940 can be configured to store software programs and modules, such as a program instruction/module corresponding to the qubit processing method and apparatus according to some embodiments of the present disclosure. Processor 920 executes various function applications and data processing by running the software programs and the modules stored in the memory, namely, the abovementioned qubit processing method is achieved. Memory 940 can include a high-speed random access memory and can also include a nonvolatile memory, such as one or more magnetic storage apparatuses, flash memories or other nonvolatile solid-state memories. In some examples, memory 940 can further include memories remotely arranged relative to the processor, and the remote memories may be connected to the computer terminal through a network. The examples of the network include but are not limited to the Internet, an intranet, a local area network, a mobile communication network and a combination thereof.

Processor 920 may call information and an application program stored in the memory through a transmission apparatus so as to execute the following steps: controlling a qubit to be biased at a preset frequency; acquiring a relationship between the frequency of a tunable resonator and a flux bias applied to the tunable resonator, the tunable resonator being a resonator coupled with the qubit; determining a target flux bias corresponding to energy level splitting of the tunable resonator based on the relationship, the energy level splitting representing that the tunable resonator resonates with the qubit; and controlling to apply the target flux bias to the tunable resonator and maintaining for a preset time period, and so as to initialize the qubit.

In some embodiments, processor 920 may also execute program codes of the following steps: acquiring a relationship between the frequency of a tunable resonator and a flux bias applied to the tunable resonator, including: measuring frequency of the tunable resonator after applying an initial flux bias to the tunable resonator, so as to obtain a measured frequency corresponding to the initial flux bias; changing the flux bias applied to the tunable resonator for multiple times based on the initial flux bias, so as to obtain measured frequencies corresponding to the flux bias through the multiple changes; and based on the measured frequency corresponding to the initial flux bias and the measured frequencies corresponding to the flux bias through the multiple changes, simulating the relationship between the frequency of the tunable resonator and the flux bias applied to the tunable resonator.

In some embodiments, the preset time period is tens to hundreds of nanoseconds.

In some embodiments, processor 920 may also execute program codes of the following steps: determining a target flux bias corresponding to energy level splitting of the tunable resonator based on the relationship, including: when a change curve showing the frequency changing along with the flux bias is adopted to represent the relationship, determining a position point where the change curve changes from one to two; and determining the flux bias corresponding to the position point as the target flux bias.

In some embodiments, the tunable resonator is a superconducting quantum interference device.

In some embodiments, processor 920 may also execute program codes of the following steps: controlling to apply the target flux bias to the tunable resonator and maintaining for a preset time period, and initializing the qubit, including: under a condition that a plurality of qubits are coupled to the tunable resonator, controlling to apply the target flux bias to the tunable resonator and maintaining for a preset time period, and performing batch initialization on the plurality of qubits.

In some embodiments, the qubits are Fluxonium qubits.

Processor 920 may call information and the application program stored in memory 940 through the transmission apparatus so as to execute the following steps: acquiring flux bias applied to a tunable resonator through multiple adjustments and measured frequencies corresponding to the flux bias subjected to the multiple adjustments, the tunable resonator being a resonator coupled with a qubit; based on the flux bias through the multiple adjustments and the measured frequencies corresponding to the flux bias through the multiple adjustments, determining a relationship between the frequency of the tunable resonator and the flux bias applied to the tunable resonator; and determining a target flux bias corresponding to energy level splitting of the tunable resonator based on the relationship, the energy level splitting representing that the tunable resonator resonates with the qubit, and initialization of the qubit being realized after the target flux bias is applied to the tunable resonator and maintained for a preset time period.

Those of ordinary skill in the art may understand that, the structure shown in FIG. 9 is only schematic, and the computer terminal may be a terminal device such as a smart phone (like an Android mobile phone or an iOS mobile phone), a tablet computer, a palmtop computer, a Mobile Internet Device (MID), or a PAD. FIG. 9 does not constitute a limitation on a structure of the foregoing electronic apparatus. For example, the computer terminal 900 may further include more or less assemblies than those shown in FIG. 9, or has different configurations from those shown in FIG. 9.

Those of ordinary skill in the art may understand that all or part of the steps in the various methods of the above embodiments may be completed by instructing the hardware related to the terminal device through a program. The program may be stored in a computer readable storage medium, and the computer readable storage medium may include: a flash disk, a Read-Only Memory (ROM), a Random Access Memory (RAM), a magnetic disk or an optical disk, and the like.

Embodiments of the present disclosure also provide a computer readable storage medium. In some embodiments, the above-mentioned computer readable storage medium may be configured to store the program code executed by the qubit processing method according to the embodiments of the present disclosure.

In some embodiments, the abovementioned computer readable storage medium may be located in any computer terminal in the computer terminal group in the computer network, or in any mobile terminal in the mobile terminal group.

In some embodiments, the computer readable storage medium is set to store program codes used for executing the following steps: controlling a qubit to be biased at a preset frequency; acquiring a relationship between the frequency of a tunable resonator and a flux bias applied to the tunable resonator, the tunable resonator being a resonator coupled with the qubit; determining a target flux bias corresponding to energy level splitting of the tunable resonator based on the relationship, the energy level splitting representing that the tunable resonator resonates with the qubit; and controlling to apply the target flux bias to the tunable resonator and maintaining for a preset time period, and so as to initialize the qubit.

In some embodiments, the computer readable storage medium is also set to store program codes used for executing the following steps: acquiring a relationship between the frequency of a tunable resonator and a flux bias applied to the tunable resonator, including: measuring frequency of the tunable resonator after applying an initial flux bias to the tunable resonator, so as to obtain a measured frequency corresponding to the initial flux bias; changing the flux bias applied to the tunable resonator for multiple times based on the initial flux bias, so as to obtain measured frequencies corresponding to the flux bias through the multiple changes; and based on the measured frequency corresponding to the initial flux bias and the measured frequencies corresponding to the flux bias through the multiple changes, simulating the relationship between the frequency of the tunable resonator and the flux bias applied to the tunable resonator.

In some embodiments, the preset time period is tens to hundreds of nanoseconds.

In some embodiments, the computer readable storage medium is also set to store program codes for executing the following steps: determining a target flux bias corresponding to energy level splitting of the tunable resonator based on the relationship, including: when a change curve showing the frequency changing along with the flux bias is adopted to represent the relationship, determining a position point where the change changes from one to two; and determining the flux bias corresponding to the position point as the target flux bias.

In some embodiments, the tunable resonator is a superconducting quantum interference device.

In some embodiments, the computer readable storage medium is also set to store program codes for executing the following steps: controlling to apply the target flux bias to the tunable resonator and maintaining for a preset time period, and initializing the qubit, including: under a condition that a plurality of qubits are coupled to the tunable resonator, controlling to apply the target flux bias to the tunable resonator and maintaining for a preset time period, and performing batch initialization on the plurality of qubits.

In some embodiments, the qubits are Fluxonium qubits.

In some embodiments, the computer readable storage medium is set to store program codes used for executing the following steps: acquiring flux bias applied to a tunable resonator through multiple adjustments and measured frequencies corresponding to the flux bias subjected to the multiple adjustments, the tunable resonator being a resonator coupled with a qubit; based on the flux bias through the multiple adjustments and the measured frequencies corresponding to the flux bias through the multiple adjustments, determining a relationship between the frequency of the tunable resonator and the flux bias applied to the tunable resonator; and determining a target flux bias corresponding to energy level splitting of the tunable resonator based on the relationship, the energy level splitting representing that the tunable resonator resonates with the qubit, and initialization of the qubit being realized after the target flux bias is applied to the tunable resonator and maintained for a preset time period.

The embodiments may further be described using the following clauses:

1. A qubit processing method, comprising:
controlling a qubit to be biased at a preset frequency;
acquiring a relationship between a frequency of a tunable resonator and a flux bias applied to the tunable resonator, the tunable resonator being a resonator coupled with the qubit;
determining a target flux bias corresponding to energy level splitting of the tunable resonator based on the relationship, the energy level splitting representing that the tunable resonator resonates with the qubit; and
applying the target flux bias to the tunable resonator for a preset time period to initialize the qubit.

2. The method according to clause 1, wherein acquiring the relationship between the frequency of the tunable resonator and the flux bias applied to the tunable resonator comprises:
measuring a frequency of the tunable resonator after applying an initial flux bias to the tunable resonator to obtain a measured frequency corresponding to the initial flux bias;
changing multiple times the flux bias applied to the tunable resonator based on the initial flux bias to obtain measured frequencies corresponding to the flux bias through multiple changes; and
based on the measured frequency corresponding to the initial flux bias and the measured frequencies corresponding to the flux bias through the multiple changes, simulating the relationship between the frequency of the tunable resonator and the flux bias applied to the tunable resonator.

3. The method according to clause 1, wherein the preset time period is tens to hundreds of nanoseconds.

4. The method according to clause 1, wherein determining the target flux bias corresponding to energy level splitting of the tunable resonator based on the relationship comprises:
when a change curve showing the frequency changing along with the flux bias is adopted to represent the relationship, determining a position point where a number of the change curve changes from one to two; and
determining a flux bias corresponding to the position point as the target flux bias.

5. The method according to clause 1, wherein the tunable resonator is a superconducting quantum interference device.

6. The method according to clause 1, wherein applying the target flux bias to the tunable resonator for a preset time period to initialize the qubit comprises:
under a condition that a plurality of qubits are coupled to the tunable resonator, applying the target flux bias to the tunable resonator for the preset time period; and
performing batch initialization on the plurality of qubits.

7. The method according to any one of clauses 1 to 6, wherein the qubit is a Fluxonium qubit.

8. A qubit processing method, comprising:
acquiring flux bias applied to a tunable resonator through multiple adjustments and measured frequencies corresponding to the flux bias subjected to the multiple adjustments, the tunable resonator being a resonator coupled with a qubit;
based on the flux bias through the multiple adjustments and the measured frequencies corresponding to the flux bias through the multiple adjustments, determining a relationship between the frequency of the tunable resonator and the flux bias applied to the tunable resonator; and
determining a target flux bias corresponding to energy level splitting of the tunable resonator based on the relationship, the energy level splitting representing that the tunable resonator resonates with the qubit, and initialization of the qubit being realized after the target flux bias is applied to the tunable resonator for a preset time period.

9. A quantum circuit, comprising:
a qubit readout resonator;
a qubit coupled with a readout line through the qubit readout resonator, and used for being biased at a preset frequency; and
a tunable resonator coupled with the readout line and coupled with the qubit, wherein the tunable resonator is configured to initialize the qubit by applying a target flux bias enabling energy level splitting of the tunable resonator for a preset time period, the energy level splitting representing that the tunable resonator resonates with the qubit.

10. The quantum circuit according to clause 9, further comprising:
a capacitor coupled with the qubit and the tunable resonator respectively, and configured to assist in initializing the qubit.

11. The quantum circuit according to clause 9, wherein the tunable resonator is a superconducting quantum interference device.

12. The quantum circuit according to clause 9, wherein the preset time period is tens to hundreds of nanoseconds.

13. A computer readable storage medium, comprising a stored program, wherein the program in running controls a device with the computer readable storage medium to execute the qubit processing method according to any one of clauses 1 to 8.

14. A computer device, comprising a memory and a processor, wherein
the memory is configured to store a computer program; and
the processor is configured to execute the computer program stored in the memory, and the processor executes the qubit processing method according to any one of clauses 1 to 8 when the computer program is running.

It should be noted that, the relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the disclosure disclosed herein. It is intended that the specification and examples be considered as exemplary only, with a true scope and spirit of the disclosure being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

It should be understood that the disclosed technical content may be implemented in other ways. The apparatus embodiments described above are only schematic. For example, the division of the units is only a logical function division. In actual implementations, there may be another division manner. For example, multiple units or components may be combined or integrated into another system, or some features can be ignored or not implemented. In addition, the displayed or discussed mutual coupling or direct coupling or communication connection may be indirect coupling or communication connection through some interfaces, units, or modules, which may be in electrical or other forms.

The units described as separate components may or may not be physically separated, and the components displayed as units may or may not be physical units, that is, they may be located in one place or may be distributed to a plurality of network units. Part of or all the units may be selected according to actual needs to achieve the purpose of the solution of the present embodiment.

In addition, the functional units in various embodiments of the present disclosure may be integrated into one processing unit, or each unit may exist alone physically, or two or more units may be integrated into one unit. The integrated units described above may be implemented either in the form of hardware or in the form of a software functional unit.

If the integrated units are implemented in the form of a software functional unit and sold or used as an independent product, they may be stored in a quantum computer-readable storage medium. Based on such an understanding, the technical solutions of the present disclosure essentially, or the part making contributions to the prior art, or all or part of the technical solutions may be embodied in the form of a software product. The quantum computer software product is stored in a storage medium and includes several instructions used for causing a quantum computer device to execute all or part of steps of the methods in various embodiments of the present disclosure.

The above are only preferred implementations of the present disclosure. It should be pointed out that, for those of ordinary skill in the art, several improvements and retouches may further be made without departing from the principles of the present disclosure. These improvements and retouches should also be regarded as the scope of protection of the present specification.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A qubit processing method, comprising:
controlling a qubit to be biased at a preset frequency;
acquiring a relationship between a frequency of a tunable resonator and a flux bias applied to the tunable resonator, the tunable resonator being a resonator coupled with the qubit;
determining a target flux bias corresponding to energy level splitting of the tunable resonator based on the relationship, the energy level splitting representing that the tunable resonator resonates with the qubit; and
applying the target flux bias to the tunable resonator for a preset time period to initialize the qubit.

2. The method according to claim 1, wherein acquiring the relationship between the frequency of the tunable resonator and the flux bias applied to the tunable resonator comprises:
measuring a frequency of the tunable resonator after applying an initial flux bias to the tunable resonator to obtain a measured frequency corresponding to the initial flux bias;
changing multiple times the flux bias applied to the tunable resonator based on the initial flux bias to obtain measured frequencies corresponding to the flux bias through the multiple changes; and
based on the measured frequency corresponding to the initial flux bias and the measured frequencies corresponding to the flux bias through the multiple changes, simulating the relationship between the frequency of the tunable resonator and the flux bias applied to the tunable resonator.

3. The method according to claim 1, wherein the preset time period is tens to hundreds of nanoseconds.

4. The method according to claim 1, wherein determining the target flux bias corresponding to energy level splitting of the tunable resonator based on the relationship comprises:
when a change curve showing the frequency changing along with the flux bias is adopted to represent the relationship, determining a position point where a number of the change curve changes from one to two; and
determining a flux bias corresponding to the position point as the target flux bias.

5. The method according to claim 1, wherein the tunable resonator is a superconducting quantum interference device.

6. The method according to claim 1, wherein applying the target flux bias to the tunable resonator for a preset time period to initialize the qubit comprises:
under a condition that a plurality of qubits are coupled to the tunable resonator, applying the target flux bias to the tunable resonator for the preset time period; and
performing batch initialization on the plurality of qubits.

7. The method according to claim 1, wherein the qubit is a Fluxonium qubit.

8. A qubit processing method, comprising:
acquiring flux bias applied to a tunable resonator through multiple adjustments and measured frequencies corresponding to the flux bias subjected to the multiple adjustments, the tunable resonator being a resonator coupled with a qubit;
based on the flux bias through the multiple adjustments and the measured frequencies corresponding to the flux bias through the multiple adjustments, determining a relationship between the frequency of the tunable resonator and the flux bias applied to the tunable resonator; and
determining a target flux bias corresponding to energy level splitting of the tunable resonator based on the relationship, the energy level splitting representing that the tunable resonator resonates with the qubit, and initialization of the qubit being realized after the target flux bias is applied to the tunable resonator for a preset time period.

9. The method according to claim 8, wherein the preset time period is tens to hundreds of nanoseconds.

10. The method according to claim 8, wherein the tunable resonator is a superconducting quantum interference device.

11. The method according to claim 8, wherein the qubit is a Fluxonium qubit.

12. A quantum circuit, comprising:
a qubit readout resonator;
a qubit coupled with a readout line through the qubit readout resonator, and used for being biased at a preset frequency; and
a tunable resonator coupled with the readout line and coupled with the qubit, wherein the tunable resonator is configured to initialize the qubit by applying a target flux bias enabling energy level splitting of the tunable resonator for a preset time period, the energy level splitting representing that the tunable resonator resonates with the qubit.

13. The quantum circuit according to claim 12, further comprising:
a capacitor coupled with the qubit and the tunable resonator respectively, and configured to assist in initializing the qubit.

14. The quantum circuit according to claim 12, wherein the tunable resonator is a superconducting quantum interference device.

15. The quantum circuit according to claim 12, wherein the preset time period is tens to hundreds of nanoseconds.
